(19) United States
(12) Patent Application Publication
(10) Pub. No.: US 2013/0234579 A1
(43) Pub. Date: Sep. 12, 2013

(54) SERVER CABINET

(71) Applicant: XIAN-XIU TANG, Shenzhen City (CN)

(72) Inventor: XIAN-XIU TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/436,982

(22) Filed: Apr. 1, 2012

(30) Foreign Application Priority Data
Mar. 8, 2012 (CN) 201210059392.X

(51) Int. Cl. H05K 5/02

(52) U.S. Cl. 312/330.1

(57) ABSTRACT

A cabinet for receiving a server includes two opposite sidewalls, two movable frames slidably mounted to rear sides of the sidewalls, and a pair of rails mounted to front sides of the sidewalls. Each rail forms a supporting piece for supporting a server together with the supporting piece of the fixing member. Each movable frame has a blocking member for blocking a rear side of the server.

### BACKGROUND

1. Technical Field

The present disclosure relates to a server cabinet.

2. Description of Related Art

Cabinets used for receiving servers only can receive servers of a particular size, which is less optimal in a situation where a variety of servers need to be accommodated.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a cabinet together with a first server; the cabinet includes two movable frames and a plurality of rails.

FIG. 2 is an enlarged view of a part of the movable frame and a part of the first server of FIG. 1.

FIG. 3 is an enlarged view of one of the rails of FIG. 1.

FIG. 4 is an assembled, isometric view of the cabinet and the first server of FIG. 1.

FIG. 5 is an enlarged view of the circled portion V of FIG. 4.

FIG. 6 is an assembled, isometric view of an exemplary embodiment of the cabinet together with a second server

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

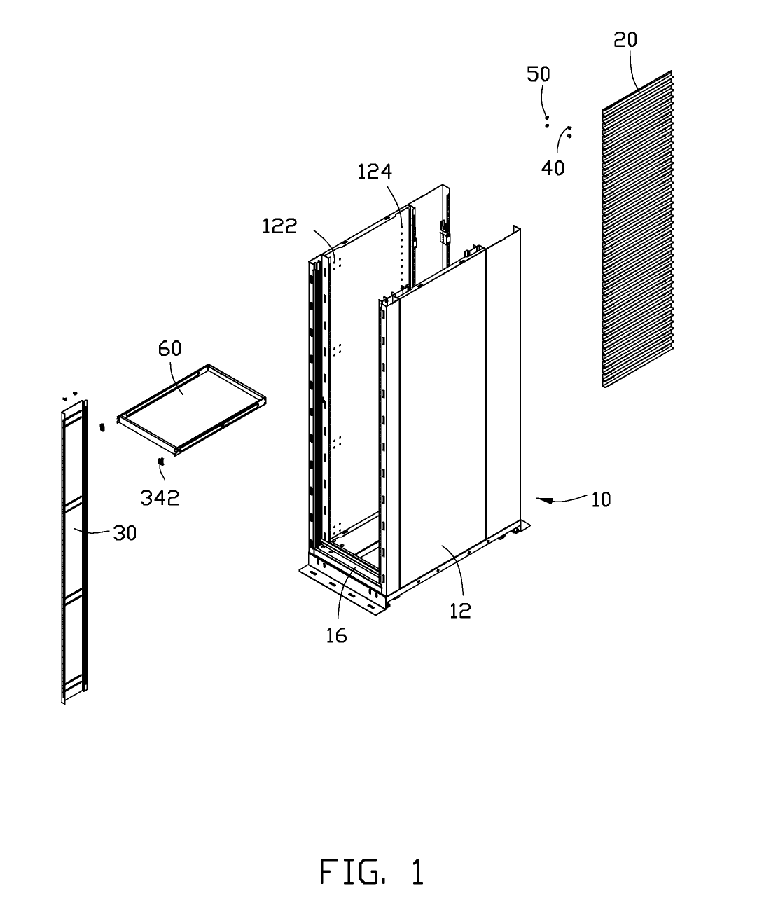

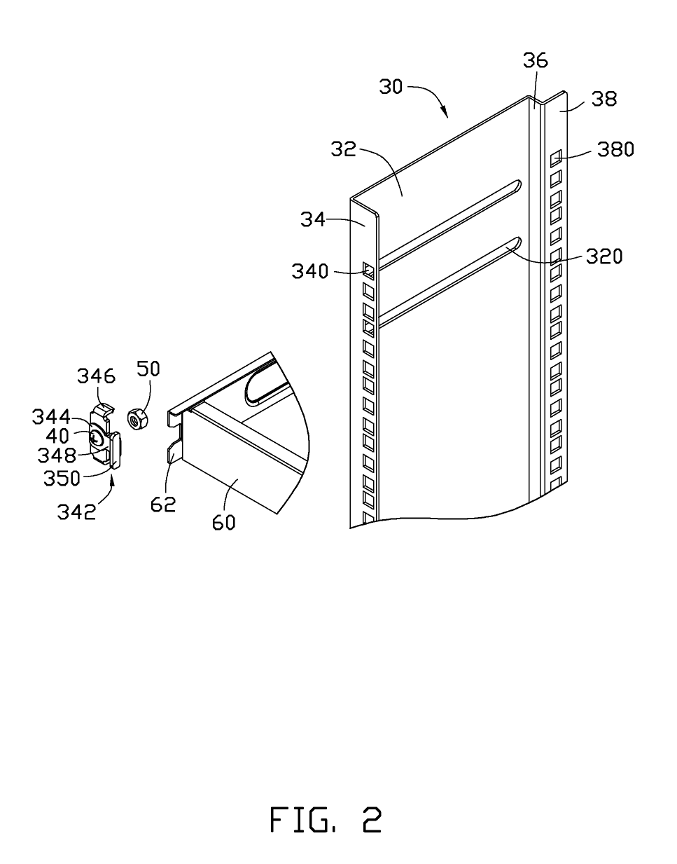

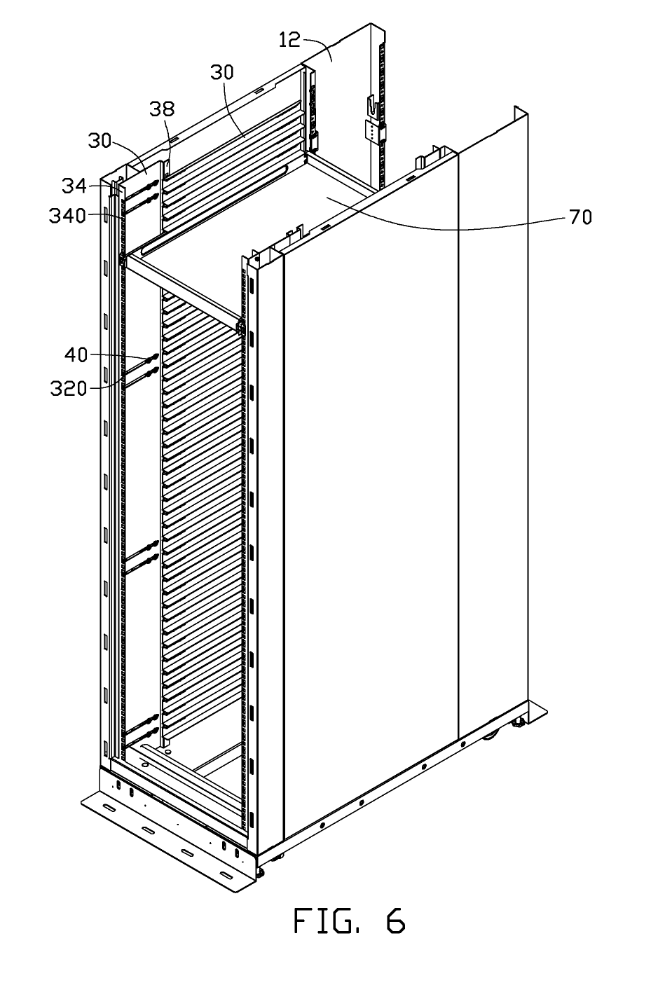

FIGS. 1 and 2 show an exemplary embodiment of a cabinet 10 for receiving a first server 60 or a second server 70 (shown in FIG. 6). The length of the second server 70 is greater than the first server 60. Two substantially U-shaped clamping portions 62 extend rearwards from rear ends of opposite sides of the servers 60 and 70.

The cabinet 10 includes two sidewalls 12, a bottom wall 16 perpendicularly connected between bottom ends of the sidewalls 12, two movable frames 30 slidably mounted to inner surfaces of rear sides of the sidewalls 12, and two rows of rails 20 mounted to inner surfaces of front sides of the sidewalls 12 opposite to the movable frames 30.

Each sidewall 12 longitudinally defines a plurality of pairs of threaded holes 122 in the rear side, and a plurality of threaded holes 124 in the front side.

Each movable frame 30 includes a main plate 32, a fixing plate 34 and an extension plate 36 perpendicularly extending out from opposite sides of the main plate 32, and an installing plate 38 in the nature of a continuous flange perpendicularly extending out from the extension plate 36 opposite to the main plate 32 away from the fixing plate 34. The main plate 32 longitudinally defines a plurality of slots 320 perpendicular to the fixing plate 34. The fixing plate 34 longitudinally defines a plurality of openings 340, and the installing plate 38 longitudinally defines a plurality of openings 380. A blocking member 342 is detachably mounted to a rear surface of the fixing plate 34 opposite to the extension plate 36, to limit the insertion of one server.

Each blocking member 342 includes a main portion 344, two curved claws 346 extending forward from top and bottom ends of the main portion 344, an extension piece 348 extending out from a side of the main portion 344, and a limiting piece 350 perpendicularly extending rearward from a distal end of the extension piece 348 opposite to the main portion 344.

The claws 346 engage in two openings 340. A bolt 40 extends through the main portion 344 and an opening 340 between the claws 346, and is screwed into a nut 50, to fix the blocking member 342 to the rear surface of the fixing plate 34.

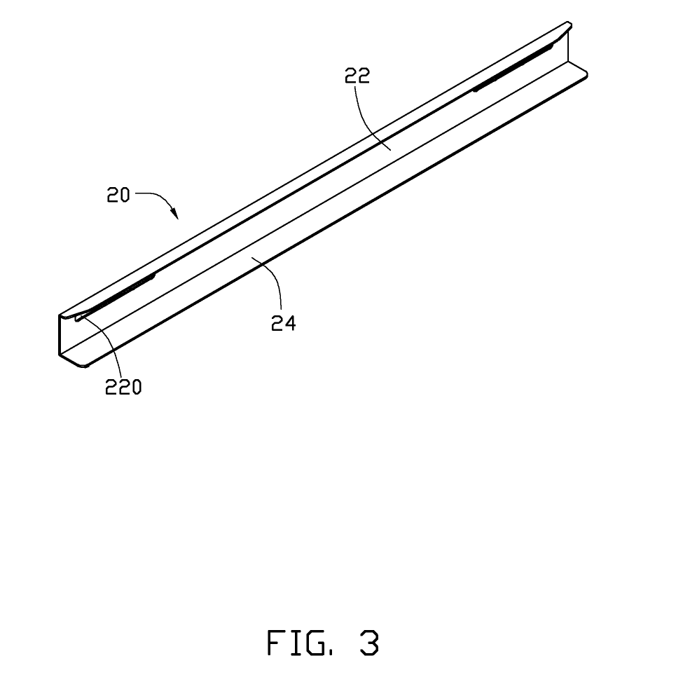

Referring FIG. 3, each rail 20 includes a fixing piece 22 and a supporting piece 24 perpendicularly extending out from a bottom side of the fixing piece 22. The fixing piece 22 defines a slot 220 adjacent to each of the front and rear ends of the fixing piece 22.

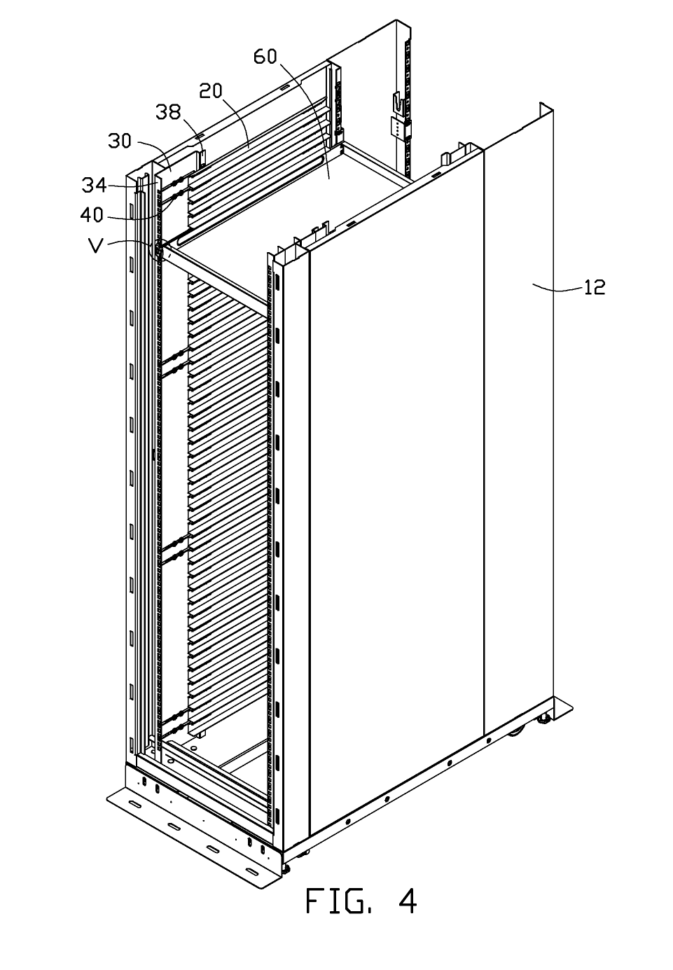

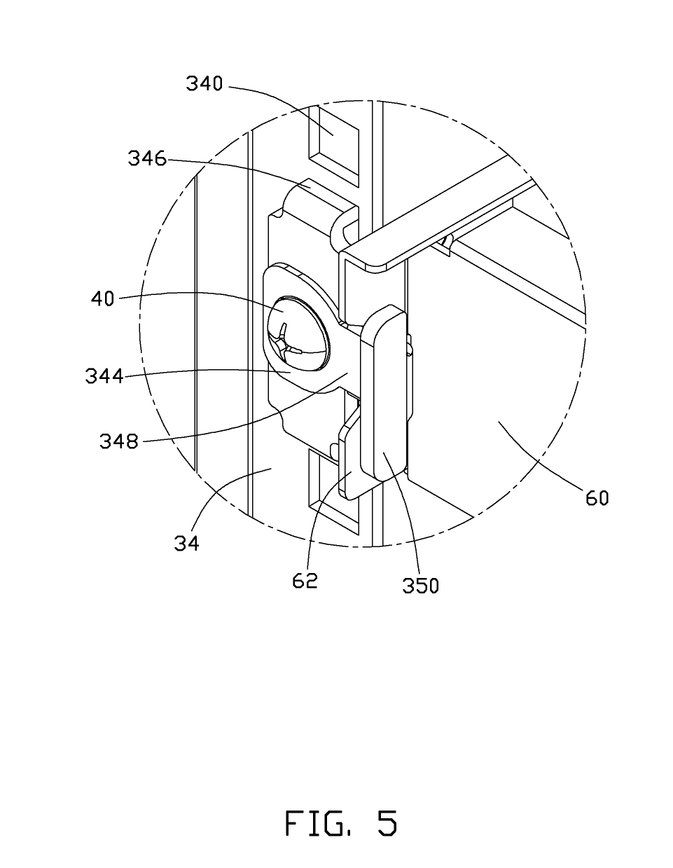

Referring FIGS. 4 and 5, in assembly, each main plate 34 is placed in contact with the inner surface of the rear side of one of the sidewalls 12. Each slot 320 is aligned with a pair of threaded holes 122. Two bolts 40 extend through each slot 320 and engage into the threaded holes 122, to slidably mount the movable frame 30 to the sidewall 12, with the bolts 40 able to slide along the slots 320.

The fixing piece 22 of each rail 20 is attached to the inner surface of the front side of one of the sidewalls 12. One of the slots 220 is aligned with one of the threaded holes 124, and the other one of the slots 220 is aligned with one of the openings 380 of the installing plate 38. A bolt 40 extends through the slot 220 and the threaded hole 124, to secure an end of the rail 20 to the front side of the sidewall 12. A bolt 40 extends through the other one of the slots 220 and the opening 380, and engages a nut 50. Thereby, the other end of the rail 20 is mounted to the movable frame 30, and the frame 30 is slidable along the slot 220 relative to the rail 20.

In use, the bolts 40 through the slots 320 are released; thereby the movable frames 30 are able to slide along the slots 320, with the bolts 40 sliding in the slots 220. After the blocking members 342 are positioned at a particular place and ready for blocking the first or second server 60 or 70, the bolts 40 are refastened. The first server 60 or the second server 70 can be slid into the cabinet 10 and be supported by two supporting pieces 24, until the clamping portions 62 each clamp an extension piece 348. At this time, the clamping portions 62 are blocked by the limiting pieces 350. A front side of the first server 60 or the second server 70 is fixed to the front sides of the sidewalls 12 with fasteners (not shown).

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A cabinet for receiving a server forming two clamping portions at a rear side, the cabinet comprising:
two opposite sidewalls;
two movable frames slidably mounted to rear sides of the sidewalls;
two rails fixed to front sides of the sidewalls opposite to the movable frames; each rail comprising a supporting piece for supporting the server together with the supporting piece of the other rail; and
two blocking members respectively attached to rear surfaces of the movable frames to block a rear side of the server.

2. The cabinet of claim 1, wherein each movable frame comprises a main plate slidably attached to an inner surface of the rear side of the corresponding sidewall, the main plate longitudinally defines at least two slots extending along the width length of the sidewall, a plurality of bolts is extended through the slots and then are engaged into the sidewall, to fix the movable frame to the sidewall.

3. The cabinet of claim 2, wherein each movable frame further comprises a fixing plate perpendicularly extending from a rear side of the main plate and longitudinally defining a plurality of openings, each blocking member comprises a main portion, two curved first claws extending from top and bottom ends of the main portion to be engaged in two openings of the corresponding fixing plate, and an extension piece extending from a side of the main portion to be clamped by a corresponding one of the clamping portions of the server.

4. The cabinet of claim 3, wherein a bolt is extended through each main portion and the opening between the corresponding claws and then is engaged with a nut, to fix the corresponding blocking member to a rear surface of the corresponding fixing plate.

5. The cabinet of claim 2, wherein each rail comprises a fixing piece perpendicularly extending from a side of the corresponding supporting piece, a front end of the fixing piece is fixed to the front side of the corresponding sidewall, a slot is defined in a rear end of the fixing piece, an extension plate perpendicularly extends out from a front side of each main plate opposite to the fixing plate, an installing plate perpendicularly extends out from a distal side of the extension plate away from the corresponding fixing plate, a bolt is extended through the slot of each fixing piece and the corresponding installing plate and then is engaged in a nut, to mount the other end of the rail to the corresponding movable frame, the frame is slidably related to the rail, with the slot of the fixing piece slidably relative to the bolt.
